(19) United States
(12) Patent Application Publication
(10) Pub. No.: US 2009/0130418 A1
(43) Pub. Date: May 21, 2009

(54) TRANSPARENT CONDUCTIVE FILM, ITS PRODUCTION METHOD AND SPUTTERING TARGET USED FOR ITS PRODUCTION

(75) Inventors: Hidefumi ODAKA, Chiyoda-ku (JP); Akira MITSUI, Chiyoda-ku (JP); Susumu NAKAGAMA, Takasago-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: ASAHI GLASS COMPANY LIMITED, Tokyo (JP)

(21) Appl. No.: 12/329,852

(22) Filed: Dec. 8, 2008

Related U.S. Application Data
(63) Continuation of application No. PCT/JP07/61638, filed on Jun. 8, 2007.

(30) Foreign Application Priority Data
Jun. 8, 2006 (JP) 2006-159526

(51) Int. Cl. B32B 15/00; C23C 14/34; C09D 1/00

(52) U.S. Cl. 428/220; 204/298.13; 204/192.29; 106/286.4

(57) ABSTRACT

Providing a tin oxide target suitable for the formation of a transparent conductive film by DC sputtering method, DC pulse sputtering method or AC sputtering method.

A sputtering target which is used for forming a transparent conductive film by a sputtering method, comprising tin oxide as the main component, and at least one element selected from the A dopant group consisting of zinc, niobium, titanium, magnesium, aluminum and zirconium and at least one element selected from the B dopant group consisting of tungsten, tantalum and molybdenum, as dopants.

### TECHNICAL FIELD

The present invention relates to a tin oxide sputtering target which is preferably used for forming a transparent conductive film by DC sputtering method, DC pulse sputtering method or AC sputtering method.

Further, the present invention relates to a transparent conductive film which is preferably used for transparent electrodes for a flat panel display (FPD) and a method for producing the transparent conductive film.

The transparent conductive film of the present invention can preferably be formed by using the above sputtering target of the present invention.

### BACKGROUND ART

Heretofore, transparent conductive films are used as transparent electrodes formed on a substrate in FPD such as a liquid crystal display (LCD), a plasma display panel (PDP) or an electroluminescence display (ELD) containing an organic EL. As materials for such transparent conductive films, indium oxide, zinc oxide and tin oxide are known. As the indium oxide, ITO (tin doped-indium oxide) is particularly popular and widely used. The reason why ITO is widely used resides in its low resistance and an excellent patterning property. However, a reserve of indium is poor, and it is desired to develop an alternative material.

Tin oxide (SnO₂) is a material expected as the alternative material. However, it is necessary to use antimony having a strong toxicity as a dopant to impart conductivity to tin oxide (for example, Patent Document 1).

Patent Document 1: JP-A-10-330924

### DISCLOSURE OF THE INVENTION

### Object to be Accomplished by the Present Invention

As a dopant other than antimony, tungsten, tantalum, etc. have been studied (for example, Applied Physics Letters, vol. 78, No. 3, p 350 (2001)).

However, in a case where a sputtering target is produced by employing only tin oxide containing tungsten or tantalum, there is a problem that its sintered density is low, and therefore for forming a transparent conductive film, DC sputtering method, DC pulse sputtering method and AC sputtering method, which are excellent in productivity, cannot be used.

On the other hand, a tin oxide target which can be used for DC sputtering, DC pulse sputtering and AC sputtering has been studied, and its realization has been shown (for example, JP-A-2005-154820). However, a film formed by employing a target shown in the above document has a high electric resistance, and a thin film which realizes a specific resistance of at most 5E−2 Ωcm, required for an alternative material for ITO, has not been obtained.

It is an object of the present invention to provide a tin oxide target which is suitable for forming a transparent conductive film by DC sputtering method, DC pulse sputtering method or AC sputtering method.

Further, it is an object of the present invention to provide a transparent conductive film preferably formed by using the above tin oxide target and a method for producing the transparent conductive film.

### Means to Accomplish the Object

The present invention provides a sputtering target which is used for forming a transparent conductive film by a sputtering method, comprising tin oxide as the main component, and at least one element selected from the A dopant group consisting of zinc, niobium, titanium, magnesium, aluminum and zirconium and at least one element selected from the B dopant group consisting of tungsten, tantalum and molybdenum, as dopants.

The sputtering target of the present invention preferably satisfies the following formulae (1) to (3):

0.8<(Sn)/(Sn+M_{A}+M_{B})<1.0 (1)

0.001<(M_{A})/(Sn+M_{A}+M_{B})<0.1 (2)

0.001<(M_{B})/(Sn+M_{A}+M_{B})<0.15 (3)

where M_{A} is the total amount of elements of the A dopant group, M_{B} is the total amount of elements of the B dopant group, and Sn is the amount of tin element contained in the sputtering target.

The sputtering target of the present invention preferably has the relative density of at least 60% and the sheet resistance on its surface of at most 9E+6Ω/□.

The present invention provides a transparent conductive film, comprising tin oxide as the main component, and at least one element selected from the A dopant group consisting of zinc, niobium, titanium, magnesium, aluminum and zirconium and at least one element selected from the B dopant group consisting of tungsten, tantalum and molybdenum, as dopants and containing substantially no antimony or indium.

The transparent conductive film of the present invention preferably satisfies the following formulae (4) to (6):

0.8<(Sn)/(Sn+M_{A}+M_{B})<1.0 (4)

001<(M_{A})/(Sn+M_{A}+M_{B})<0.1 (5)

0.001<(M_{B})/(Sn+M_{A}+M_{B})<0.15 (6)

where M_{A} is the total amount of elements of the A dopant group, M_{B} is the total amount of elements of the B dopant group, and Sn is the amount of tin element contained in the sputtering target.

The transparent conductive film of the present invention preferably has the specific resistance of at most 5E−2 Ωcm.

The transparent conductive film of the present invention preferably has a thickness of at most 1 μm.

Further, the present invention provides a display member, which has the transparent conductive film of the present invention.

Further, the present invention provides a method for producing a transparent conductive film, which comprises forming the transparent conductive film of the present invention by a sputtering method using the sputtering target of the present invention.

### EFFECT OF THE INVENTION

The sputtering target of the present invention has a high sintered density and a low surface sheet resistance and thereby is preferably used as a sputtering target for forming a transparent conductive film by DC sputtering method, DC pulse sputtering method and AC sputtering method.

A transparent conductive film formed by using the sputtering target of the present invention is comparable to conventional transparent conductive films in the properties required for transparent electrodes of FPD such as relative resistance or visible light transmittance.

Further, since a transparent conductive film to be formed does not contain expensive indium, it is possible to provide a transparent conductive film with a low cost. Further, since antimony and indium having toxicity are not contained, it is excellent from the viewpoint of environment.

### BEST MODE FOR CARRYING OUT THE INVENTION

The sputtering target of the present invention is characterized by comprising tin oxide as the main component and at least one element selected from the A dopant group consisting of zinc, niobium, titanium, aluminium, magnesium and zirconium and at least one element selected from the B dopant group consisting of tungsten, tantalum and molybdenum as dopants. Further, “comprising tin oxide as the main component” means that the content of tin oxide is at least 75 mol % as calculated as tin element. More specifically, in the metal elements constructing a target, the ratio of tin element is preferably at least 75 mol %, more preferably at least 80 mol %.

In the sputtering target of the present invention, the element of the B dopant group (tungsten, tantalum and molybdenum) is contained as a dopant in a sintered target comprising tin oxide as the main component (hereinafter, may sometimes referred to as “tin oxide target”) in order to impart conductivity to a film formed by sputtering.

Here, as the element of the B dopant group, In or Ga, which has been conventionally used as the dopant for tin oxide target, is not preferred. Because such a dopant has a problem that oxygen pores are formed in a film, and carrier is formed, and therefore if the film is exposed to a high temperature, the electric resistance of the film becomes high.

However, tin oxide targets containing only the B dopant group element cannot be used for forming transparent electrodes for FPD by DC sputtering method, DC pulse sputtering method or RF sputtering method due to any one of the following reasons.

(1) Since the sintered density of a target is low, sufficient mechanical strength cannot be obtained, and the target cannot be molded (mechanically processed) to a target for sputtering. The reason why the sintered density of the target containing only the B dopant group element is low resides in that tin oxide powders are not sufficiently be bonded to one another.

(2) Even if the target can be molded to a target for sputtering, the sheet resistance of a target to be obtained is high, and DC electric discharge, DC pulse electric discharge and AC electric discharge thereby cannot be carried out.

The reason why the sheet resistance of the target containing only the B dopant group on a film surface is high also resides in that tin oxide powders cannot sufficiently be bonded to one another, and electric loss results at the vicinity of binding interface of powders.

In the case of the sputtering target of the present invention, the tin oxide target contains the A dopant group element (zinc, niobium, titanium, magnesium, aluminium and zirconium) as a dopant in addition to the B dopant group element, and the target thereby can be used for DC sputtering, DC pulse sputtering, and RF sputtering. Specifically, since the sintered density of the target is high, the target has a sufficient mechanical strength so as to be molded to a target for sputtering. Further, since the surface resistance of the target, specifically the sheet resistance of the target is sufficiently low, DC sputtering, DC pulse sputtering and AC sputtering can be carried out.

The sputtering target of the present invention may contain one element selected from the A dopant group or may contain at least two elements selected from the A dopant group. Similarly, the sputtering target of the present invention may contain one element selected from the B dopant group or at least two elements selected from the B dopant group.

Among the elements of the A dopant group, zinc or niobium is preferably contained since the higher sintered density can be obtained.

On the other hand, among the B dopant group, tantalum is preferably contained since the lower resistance can be obtained.

The sputtering target of the present invention preferably satisfies the following formulae (1) to (3):

0.8<(Sn)/(Sn+M_{A}+M_{B})<1.0 (1)

0.001<(M_{A})/(Sn+M_{A}+M_{B})<0.1 (2)

0.001<(M_{B})/(Sn+M_{A}+M_{B})<0.15 (3)

where M_{A} is the total amount of elements of the A dopant group, M_{B} is the total amount of elements of the B dopant group, and Sn is the amount of tin element contained in the sputtering target. In the present invention M_{A}, M_{B} and Sn are represented by mol %, unless otherwise specified.

When the sputtering target of the present invention satisfies the above formulae (1) to (3), a target having a relative density of at least 60% obtained by the following formula (7) can be easily obtained.

Relative density(%)=(bulk density/true density)×100 (7)

Here, bulk density (g/cm³) is an actually measured density obtained from the size and weight of a produced target, and true density is a theoretical density obtained by calculating a theoretical density specific to substance.

When the relative density of the sputtering target is at least 60%, the target has a sufficient mechanical strength for molding it to a target for sputtering.

Further, when the sputtering target of the present invention satisfies the above formulae (1) to (3), the sheet resistance of the target surface tends to be at most 9E+6Ω/□. Here, “E+6” means 10⁶. When the sheet resistance of the target surface is at most 9E+6Ω/□, the surface resistance of the target is sufficiently low, and the target is suitable as a target for sputtering by DC sputtering, DC pulse sputtering or RF sputtering.

The relative density of the sputtering target is preferably at least 60%, more preferably at least 80%.

The sheet resistance of the sputtering target surface is preferably at most 9E+6Ω/□, more preferably at most 1E+6Ω/□.

The sputtering target of the present invention preferably satisfies the following formulae (8) to (10):

0.75<(Sn)/(Sn+M_{A}+M_{B})<0.98 (8)

0.003<(M_{A})/(Sn+M_{A}+M_{B})<0.08 (9)

0.05<(M_{B})/(Sn+M_{A}+M_{B})<0.20 (10)

where M_{A}, M_{B} and Sn are as defined above.

Further, the formula (8) preferably satisfies the following formula (8′), particularly preferably satisfies the following formula (8″).

0.75<(Sn)/(Sn+M_{A}+M_{B})<0.95 (8′)

0.80<(Sn)/(Sn+M_{A}+M_{B})<0.95 (8″)

The sputtering target of the present invention can be produced by a conventional procedure for forming a sintered oxide target. Namely, the sputtering target of the present invention can be produced by preparing materials so as to have the desired composition, followed by molding under applied pressure and then by sintering in an atmosphere at a high temperature (for example, 1,200° C.) under atmospheric pressure.

At a high temperature, firing must be carried out under atmospheric pressure. Under a reduced pressure or in an argon atmosphere, tin oxide tends to decompose and evaporate, and it is thereby difficult to dense the target. Therefore, in such a case, sintering is preferably carried out in an atmosphere containing oxygen, such as air. For example, sintering is carried out in air at a temperature of 1,000 to 1,600° C.

In the case of sintering in air, a target may, for example, be produced in the following manner. SnO₂ powder and oxide powders of respective dopants are prepared and mixed in a predetermined ratio. At that time, with water as a dispersant, they are mixed by a wet type ball mill method. Then, the mixed powder is dried, packed in a rubber mold and pressure-molded by a cold isostatical press machine (CIP machine) at pressure of 1,500 kg/cm². Then, sintering is carried out in air at a temperature of 1,000 to 1,600° C. to obtain a sintered body. The sintered body is mechanically processed to a desired size to produce a target material. The target material is metal-bonded on a backing plate made of a metal such as copper, whereby the target is produced.

The particle size of SnO₂ powder is preferably at most 10 μm, more preferably at most 5 μm as the average particle size. It is further preferably at most 1 μm.

Further, the average particle size of oxide powders of respective dopants is preferably at most 30 μm, more preferably at most 5 μm. When the crystal size of the sintered body obtained by the above procedure is measured by SEM, it is confirmed that the sintered body is from 1 to 50 μm. Further, in the present invention, the average particle size means a central value of the particle size distribution of the powder.

The transparent conductive film of the present invention is characterized by comprising tin oxide as the main component, and at least one element selected from the A dopant group consisting of zinc niobium titanium, magnesium, aluminium and zirconium and at least one element selected from the B dopant group consisting of tungsten, tantalum and molybdenum, as dopants and containing substantially no antimony or indium. Here, “comprising tin oxide as the main component” means that the content of tin oxide is at least 75 mol %, preferably at least 80 mol % as calculated as tin element. The transparent conductive film of the present invention is suitable for transparent electrodes for FPD such as PDP.

The transparent conductive film of the present invention is formed by preferably carrying out DC sputtering, DC pulse sputtering or RF sputtering by using the sputtering target of the present invention.

In general, as a method for forming a large area film, a sputtering method, in which a uniform thin film can be easily obtained, and pollution is little, is suitable. The sputtering method is generally classified into a high frequency (RF) sputtering method using a high frequency power source, a direct current (DC) sputtering method using a direct current, a direct current (DC) pulse sputtering method and an alternative current (AC) sputtering method using alternating current. The RF sputtering method is excellent, since an insulating material can be used as a target, however, a high frequency current power source is expensive, and its structure is complicate. And, the RF sputtering method is not suitable for forming a film with a large area.

On the other hand, in the case of the DC sputtering method, DC pulse sputtering method and AC sputtering method, although target materials are limited to a material having an excellent conductivity, a direct current or alternating current is used, and the structure of apparatus is thereby simple, and they have advantage from the viewpoint of controlling the film thickness. Accordingly, as an industrial method for forming film, the DC sputtering method, DC pulse sputtering method and AC sputtering method, which are excellent in productivity are preferred. Further, as the sputtering method, without using the RF sputtering, using the DC sputtering method, DC pulse sputtering method or AC sputtering method is one of important factors for feasibility assessment of a business from the viewpoint of productivity.

Further, the method for producing the transparent conductive film of the present invention is not particularly limited, so far as the above characteristics are satisfied. Accordingly, the transparent conductive film of the present invention may be produced by another sputtering method such as a RF sputtering method or may be produced by using another film forming method such as a CVD method, sol-gel method or PLD method.

In a case where a film is formed by the sputtering method, the sputtering is preferably carried out in an oxidative atmosphere. The oxidative atmosphere is an atmosphere containing an oxidative gas. The oxidative gas means a gas containing oxygen atoms such O₂, H₂O, CO or CO₂. The concentration of the oxidative gas influences properties of the film such as conductivity or transmittance of the film. Accordingly, it is necessary to optimize the concentration of the oxidative gas depending on a condition such as the apparatus, temperature of substrate or sputtering pressure.

As the gas for sputtering, Ar—O₂ gas (mixed gas containing Ar and O₂) or Ar—CO₂ gas (mixed gas containing Ar and CO₂) is preferred, since the composition of gas can be easily controlled for forming a transparent film of which the resistance is low. Particularly, Ar—CO₂ gas is preferred from the viewpoint of the controllability.

In the case of the Ar—O₂ gas, the concentration of O₂ is preferably from 1 to 25 vol % so that a transparent low resistance film can be formed. If the concentration of O₂ is less than 1 vol %, the film may be colored yellow, and the resistance of the film may be high. If the concentration of O₂ exceeds 25 vol %, the resistance of the film may be high.

Further, in the case of the Ar—CO₂ gas, the concentration of CO₂ is preferably from 10 to 50 vol % so that a transparent low resistance film can be formed. If the concentration of CO₂ is less than 10 vol %, the film may be colored yellow, and the resistance of the film may be high. If the concentration of CO₂ exceeds 50 vol %, the resistance of the film may be high. However, in some applications, a colored film or a high resistance film may sometimes be required. In such a case, the respective concentrations are not limited to the above ranges.

For example, the transparent conductive film of the present invention may be produced by the following method. By using a magnetron DC sputtering apparatus and the above target, the chamber is vacuumed to 10⁻⁷ to 10⁻⁴ Torr. If the pressure in the chamber exceeds 10⁻⁴ Torr, it is difficult to control the resistance due to influence of a moisture reside remaining in vacuum. Further, if the pressure in the chamber is less than 10⁻⁷ Torr, the time required for vacuuming becomes long, and the productivity deteriorates. The electric power density (a value obtained by dividing the applied electricity by the area of the target surface) at the time of the sputtering is preferably from 1 to 10 W/cm². If the electric power density is less than 1 W/cm², electric discharge is not stable. If the electric power density exceeds 10 W/cm², the possibility of breakage due to heat generated from the target may be high. The sputtering pressure is preferably from 10⁻⁴ to 10⁻¹ Torr. If the sputtering pressure is less than 10⁻⁴ Torr, or the sputtering pressure exceeds 10⁻¹ Torr, the electric discharge tends not to be stable.

The transparent conductive film of the present invention preferably satisfies the following formulae (4) to (6):

0.8<(Sn)/(Sn+M_{A}+M_{B})<1.0 (4)

001<(M_{A})/(Sn+M_{A}+M_{B})<0.1 (5)

0.001<(M_{B})/(Sn+M_{A}+M_{B})<0.15 (6)

where M_{A} is the total amount of elements of the A dopant group, M_{B} is the total amount of elements of the B dopant group, and Sn is the amount of tin element contained in the sputtering target.

When the above (4) to (6) are satisfied, a transparent conductive film having specific resistance value of at most 5E−2 Ωcm can easily be obtained, which is suitable for transparent electrodes for FPD. The specific resistance of the transparent conductive film is more preferably at most 1.0E−2 Ωcm, further preferably at most 0.5E−2 Ωcm.

The film thickness of the transparent conductive film of the present invention is preferably at most 1 μm. When the film thickness is at most 1 μm, optical defects of the transparent conductive film such as haze can be prevented. The film thickness of the transparent conductive film is more preferably at most 0.4 μm, further preferably at most 0.25 μm.

It is preferred that the transparent conductive film of the present invention is excellent in transparency. Specifically, visible transmittance is preferably at least 80%, more preferably at least 85%.

Since the transparent conductive film of the present invention does not contain expensive indium, it is possible to provide a transparent conductive film at a low cost. Further, since the transparent conductive film of the present invention does not contain antimony or indium, the transparent conductive film is environmentally excellent, and the specific resistance becomes low. The content of indium element contained in the transparent conductive film is preferably at most 0.1%. Further, the content of antimony element contained in the transparent conductive film is preferably at most 0.1%.

In order to further lower the specific resistance of the transparent conductive film, the transparent conductive film of the present invention preferably satisfies the following formulae (11) to (13):

0.75<(Sn)/(Sn+M_{A}+M_{B})<0.98 (11)

0.003<(M_{A})/(Sn+M_{A}+M_{B})<0.08 (12)

0.05<(M_{B})/(Sn+M_{A}+M_{B})<0.20 (13)

Further, the formula (11) preferably satisfies the following formula (11′), particularly preferably the following formula (11″):

0.75<(Sn)/(Sn+M_{A}+M_{B})<0.95 (11′)

0.08<(Sn)/(Sn+M_{A}+M_{B})<0.95 (11″)

In the formulae (11) to (13), M_{A}, M_{B} and Sn are as defined in the formulae (4) to (6).

The display member of the present invention is a substrate for FPD such as PDP, particularly one used as a front substrate of FPD. For example, a glass substrate or a resin substrate on which the transparent conductive film of the present invention is formed as transparent electrodes may be mentioned.

The glass substrate is not particularly limited and for example, conventional various glass substrates (soda-lime glass, non-alkali glass, etc.) may be used. As one of preferred embodiments, a high distortion glass for PDP may be mentioned. Further, its size or thickness is not particularly limited. For example, a glass of which length and width are about from 400 to 3,000 mm respectively may preferably be used. Further, its thickness is preferably from 0.7 to 3.0 mm, more preferably from 1.5 to 3.0 mm.

The display member of the present invention may be used as a substrate for various FPD in addition to PDP. The FPD may, for example, be a liquid crystal display (LCD), electroluminescence display (ELD) containing an organic EL or field emission display (FED).

### EXAMPLES

Now, the present invention will be described in further detail with reference to Examples. However, the present invention is by no means restricted to such specific Examples. Namely, the comprehensive range of the present invention is defined by the claims and includes various embodiments in addition to the following Examples.

### Examples 1 to 8

By using SnO₂, Ta₂O₅, WO₃, ZnO and Nb₂O₅ powders having a purity of about 99.9% and a particle size of at most 5 μm, a powder was prepared so that the composition ratio of the respective metal elements becomes the composition ratio shown in Table 1. The powder was mixed by means of a ball mill, pressure-molded and sintered for four hours in the atmosphere at 1,450° C., and the sintered oxide body was processed into a target shape by a machine. The composition, the relative density and the surface resistance (sheet resistance of the surface) of the obtained sintered oxide body are shown in Table 1. The sheet resistance of the surface of the target was measured by a surface resistance measuring apparatus (LORESTA, manufactured by Mitsubishi Petrochemical Co., Ltd.). Further, the relative density was obtained by the following formula (7).

Relative density(%)=(bulk density/true density)×100 (7)

Here, bulk density (g/cm³) is an actually measured density obtained from the size and weight of a produced target, and true density is a theoretical density obtained by calculating a theoretical density specific to substance.

A high distortion glass having a thickness of 2.8 mm (PD200, manufactured by Asahi Glass Company, Limited, visible transmittance of a substrate: 91%) was prepared as a glass substrate. The glass substrate was washed and then set on a substrate holder of the sputtering apparatus. Further, a sintered oxide target having the composition shown in Table 1 was set on a cathode of magnetron DC sputtering apparatus. The inside of a film forming chamber of the sputtering apparatus was evacuated, and a film containing tin oxide as the main component and having the thickness of about 150 nm was formed on the glass substrate. As the sputtering gas, a mixed gas containing argon and oxygen was used. The temperature of the substrate was 250° C. The pressure at the time of film forming was 0.5 Pa.

By changing the flow ratio of argon gas and oxygen gas, it was possible to form a transparent low electric resistance thin film. Table 2 shows the composition, visible transmittance and specific resistance of films which were formed by controlling the gas ratio so that the electric resistance became the lowest. Here, the composition, visible transmittance and specific resistance of films were measured by the following methods.

(1) Composition: A film having a thickness of 300 nm was produced under the same process condition as in the case of the film formation on the glass substrate. A fluorescent amount emited from metal elements in the formed film was measured by a fluorescent X ray apparatus (RIX3000, manufactured by Rigaku Industrial Corp.), and the amounts of the respective metal elements and the composition ratio were calculated by fundamental parameter theoretical calculation.

(2) Visible light transmittance: In accordance with JIS-R3106 (year 1998), by using a spectrophotometer (U-4100, manufactured by Shimadzu Corporation), visible light transmittance of the glass substrate with the film was calculated from transmittance spectral of the glass substrate with the formed film.

(3) Specific resistance: The specific resistance was measured by a surface resistance measuring apparatus (LORESTA, manufactured by Mitsubishi Petrochemical Co., Ltd.).

From Table 1, it is evident that each of the sintered oxide targets obtained in Examples 1 to 10 has a relative density of at least 60% and a surface resistance of at most 9E+6Ω/□. Therefore, they can be used for DC sputtering method, DC pulse sputtering method and Ac sputtering method. Further, from Table 2, it is evident that each of the films formed in Examples 1 to 10 has a visible light transmittance of at least 85% and a specific resistance of at most 1E−2 Ωcm. Therefore, they have appropriate properties required for transparent electrodes for FPD such as PDP.

### Comparative Examples 1 to 5

Sintered oxide targets having the compositions shown is in Table 1 were produced in the same manner as in Examples. Further, in Comparative Examples 4 and 5, a powder (In₂O₅ and Ga₂O₃) having a purity of about 99.9% and a particle size of at most 5 μm was used.

As a result, the sintered density of each sintered oxide target containing no element of the A dopant group (Comparative Examples 1 to 3) was low at a level of at most 60%, and when each of the sintered bodies of Comparative Examples was processed into a target shape by machine, breakage resulted, and it could not be processed into a target. On the other hand, targets containing indium or gallium as the B dopant group element (Comparative Examples 4 and 5) had a high sintered density and showed a sheet resistance useful for DC sputtering. However, a film formed by using such a target had a high specific resistance as shown in Table 2, and it was not useful for transparent electrodes for FPD.

TABLE 1
Composition, density and electric resistance of target

| | | | | | Target | Surface |
|---|---|---|---|---|---|---|
| | Used element | (Sn)/(Sn + M_{A} + M_{B}) | (M_{A})/(Sn + M_{A} + M_{B}) | (M_{B})/(Sn + M_{A} + M_{B}) | density (%) | resistance (Ω/□) |
| Ex. 1 | M_{A} = Zn | 0.961 | 0.009 | 0.029 | 60.3 | 0.3M |
| | M_{B} = Ta | | | | | |
| Ex. 2 | M_{A} = Zn | 0.926 | 0.009 | 0.065 | 60.7 | 0.3M |
| | M_{B} = Ta | | | | | |
| Ex. 3 | M_{A} = Zn | 0.887 | 0.0010 | 0.103 | 73 | 0.02k |
| | M_{B} = Ta | | | | | |
| Ex. 4 | M_{A} = Zn | 0.950 | 0.010 | 0.040 | 99 | 0.3M |
| | M_{B} = W | | | | | |
| Ex. 5 | M_{A} = Zn | 0.930 | 0.020 | 0.050 | 99 | 0.01 |
| | M_{B} = W | | | | | |
| Ex. 6 | M_{A} = Zn | 0.961 | 0.009 | 0.029 | 87.5 | 0.3M |
| | M_{B} = W | | | | | |
| Ex. 7 | M_{A} = Zn | 0.926 | 0.009 | 0.01 | 88.3 | 0.3M |
| | M_{B} = W | | | | | |
| Ex. 8 | M_{A} = Zn | 0.887 | 0.010 | 0.01 | 95.4 | 0.02k |
| | M_{B} = W | | | | | |
| Ex. 9 | M_{A} = Zn | 0.950 | 0.010 | 0.040 | 99 | 0.01k |
| | M_{B} = Ta | | | | | |
| Ex. 10 | M_{A} = Zn | 0.930 | 0.020 | 0.050 | 99 | 0.01 |
| | M_{B} = Ta | | | | | |
| Comp. | M_{A} = not used | 1.00 | 0.00 | 0.00 | 52.0 | 0.04M |
| Ex. 1 | M_{B} = not used | | | | | |
| Comp. | M_{A} = not used | 0.970 | 0.00 | 0.03 | 43.0 | 20M |
| Ex. 2 | M_{B} = W | | | | | |
| Comp. | M_{A} = not used | 0.970 | 0.00 | 0.03 | 45.0 | 35M |
| Ex. 3 | M_{B} = Ta | | | | | |
| Comp. | M_{A} = Zn | 0.67 | 0.25 | 0.08 | 96.0 | 0.02k |
| Ex. 4 | M_{B} = In | | | | | |
| Comp. | M_{A} = Zn | 0.61 | 0.21 | 0.18 | 95.0 | 0.04k |
| Ex. 5 | M_{B} = Ga | | | | | |

TABLE 2
Composition, density and electric resistance of film

| | | | | | Visible light | Specific |
|---|---|---|---|---|---|---|
| | Used | | | | transmittance | resistance |
| | element | (Sn)/(Sn + M_{A} + M_{B}) | (M_{A})/(Sn + M_{A} + M_{B}) | (M_{B})/(Sn + M_{A} + M_{B}) | (%) | (Ωcm) |
| Ex. 1 | M_{A} = Zn | 0.961 | 0.009 | 0.029 | 84.9 | 0.0055 |
| | M_{B} = Ta | | | | | |
| Ex. 2 | M_{A} = Zn | 0.926 | 0.009 | 0.065 | 85.9 | 0.0032 |
| | M_{B} = Ta | | | | | |
| Ex. 3 | M_{A} = Zn | 0.887 | 0.0010 | 0.103 | 86.4 | 0.0051 |
| | M_{B} = Ta | | | | | |
| Ex. 4 | M_{A} = Zn | 0.950 | 0.010 | 0.040 | 86 | 0.0032 |
| | M_{B} = W | | | | | |
| Ex. 5 | M_{A} = Zn | 0.926 | 0.009 | 0.065 | 86.6 | 0.0053 |
| | M_{B} = W | | | | | |
| Ex. 6 | M_{A} = Zn | 0.887 | 0.010 | 0.103 | 87.2 | 0.0088 |
| | M_{B} = W | | | | | |
| Ex. 7 | M_{A} = Nb | 0.955 | 0.035 | 0.01 | 86.2 | 0.0043 |
| | M_{B} = Ta | | | | | |
| Ex. 8 | M_{A} = Nb | 0.955 | 0.035 | 0.01 | 87.7 | 0.0065 |
| | M_{B} = W | | | | | |
| Ex. 9 | M_{A} = Zn | 0.950 | 0.010 | 0.040 | 99 | 0.0032 |
| | M_{B} = Ta | | | | | |
| Ex. 10 | M_{A} = Zn | 0.930 | 0.020 | 0.050 | 99 | 0.0033 |
| | M_{B} = Ta | | | | | |
| Comp. | M_{A} = Zn | 0.67 | 0.25 | 0.08 | 86.7 | 10.56 |
| Ex. 4 | M_{B} = In | | | | | |
| Comp. | M_{A} = Zn | 0.61 | 0.21 | 0.18 | 87.2 | 1293.22 |
| Ex. 5 | M_{B} = Ga | | | | | |

### INDUSTRIAL APPLICABILITY

The sputtering target of the present invention is suitable for the formation of a transparent conductive film by DC sputtering method, DC pulse sputtering method and AC sputtering method.

The transparent conductive film obtained by the present invention is excellent in transparency and conductivity and has excellent properties required for transparent electrodes of FPD. Further, the transparent conductive film of the present invention does not contain expensive indium and thereby can be provided at a low cost. Since the transparent conductive film of the present invention does not contain antimony having toxicity, it is environmentally excellent. Further, in a case where the transparent conductive film is applied to the laser patterning technique, which is being remarkably developed in recent years, fine electrode patterns can be formed on glass, plastic substrate, film substrate or crystal substrate.

The entire disclosure of Japanese Patent Application No. 2006-159526 filed on Jun. 8, 2006 including specification, claims and summary is incorporated herein by reference in its entirety.

What is claimed is:

1. A sputtering target which is used for forming a transparent conductive film by a sputtering method, comprising tin oxide as the main component, and at least one element selected from the A dopant group consisting of zinc, niobium, titanium, magnesium, aluminum and zirconium and at least one element selected from the B dopant group consisting of tungsten, tantalum and molybdenum, as dopants.

2. The sputtering target according to claim 1, wherein the following formulae (1) to (3) are satisfied:
0.8<(Sn)/(Sn+M_{A}+M_{B})<1.0 (1)
0.001<(M_{A})/(Sn+M_{A}+M_{B})<0.1 (2)
0.001<(M_{B})/(Sn+M_{A}+M_{B})<0.15 (3)
where M_{A} is the total amount of elements of the A dopant group, M_{B} is the total amount of elements of the B dopant group, and Sn is the amount of tin element contained in the sputtering target.

3. The sputtering target according to claim 1, wherein the relative density is at least 60%, and the sheet resistance on its surface is at most 9E+6Ω/□.

4. A transparent conductive film, comprising tin oxide as the main component, and at least one element selected from the A dopant group consisting of zinc, niobium, titanium, magnesium, aluminum and zirconium and at least one element selected from the B dopant group consisting of tungsten, tantalum and molybdenum, as dopants and containing substantially no antimony or indium.

5. The transparent conductive film according to claim 4, wherein the following formulae (4) to (6) are satisfied:
0.8<(Sn)/(Sn+M_{A}+M_{B})<1.0 (4)
001<(M_{A})/(Sn+M_{A}+M_{B})<0.1 (5)
0.001<(M_{B})/(Sn+M_{A}+M_{B})<0.15 (6)
where M_{A} is the total amount of elements of the A dopant group, M_{B} is the total amount of elements of the B dopant group, and Sn is the amount of tin element contained in the sputtering target.

6. The transparent conductive film according to claim 4, wherein the specific resistance is at most 5E−2 Ωcm.

7. The transparent conductive film according to claim 4, wherein the thickness of the transparent conductive film is at most 1 μm.

8. A display member, which has the transparent conductive film as defined in claim 4.

9. A method for producing a transparent conductive film, which comprises forming a transparent conductive film by a sputtering method using the sputtering target as defined in claim 1.
